(19) United States
(12) Patent Application Publication
(10) Pub. No.: US 2025/0054668 A1
(43) Pub. Date: Feb. 13, 2025

(54) MAGNET ASSEMBLY, DEPOSITION DEVICE INCLUDING MAGNET ASSEMBLY, AND DEPOSITION METHOD USING DEPOSITION DEVICE

(71) Applicant: Samsung Display Co., LTD., Yongin-si (KR)

(72) Inventors: Jung Hyun AHN, Yongin-si (KR); Jae Suk MOON, Yongin-si (KR); Seung Jin LEE, Yongin-si (KR)

(73) Assignee: Samsung Display Co., LTD., Yongin-si (KR)

(21) Appl. No.: 18/666,208

(22) Filed: May 16, 2024

(30) Foreign Application Priority Data
Aug. 8, 2023 (KR) 10-2023-0103715

(51) Int. Cl. H01F 7/02; B05D 1/04; B05D 1/32

(52) U.S. Cl. CPC H01F 7/0221; B05D 1/04; B05D 1/32

(57) ABSTRACT

A magnet assembly includes a yoke plate disposed on a plane, and a magnetic field generator which is disposed on the yoke plate and includes magnet parts including magnet units, magnetic bodies, and non-magnetic bodies. The magnetic bodies overlap the magnet parts in a plan view. The non-magnetic bodies overlap an area between the magnet units in a plan view. The magnet assembly operates in one of a first mode and a second mode. The magnetic field generator generates a magnetic field below the magnetic bodies and the non-magnetic bodies in the first mode and does not substantially generate the magnetic field below the magnetic bodies and the non-magnetic bodies in the second mode.

### CROSS-REFERENCE TO RELATED APPLICATION(S)

This application claims priority to and benefits of Korean patent application No. 10-2023-0103715 under 35 U.S.C. § 119, filed on Aug. 8, 2023, in the Korean Intellectual Property Office (KIPO), the entire contents of which are incorporated herein by reference.

### BACKGROUND

### 1. Technical Field

The disclosure relates to a magnet assembly, a deposition device including the magnet assembly, and a deposition method using the deposition device.

### 2. Description of the Related Art

Recently, as interest in information display is increasing, research and development on display devices is continuously made.

Display devices may include layers containing various materials. For example, display devices may each include an anode, a cathode, and an organic emission layer disposed between the anode and the cathode.

Organic emission layers may be formed through various methods. For example, organic emission layers may be formed through a deposition process using a fine metal mask (FMM).

In order to implement a high-resolution display device, structures forming the display device are becoming finer, and accordingly, there is a need to more finely control a deposition process.

### SUMMARY

The disclosure provides a magnet assembly in which a deposition process is more finely controlled, thereby manufacturing a high-resolution display device, a deposition device including the magnet assembly, and a deposition method using the deposition device.

The disclosure provides a magnet assembly in which a risk of mechanical deformation of a substrate or the like during a deposition process may be reduced, a deposition device including the magnet assembly, and a deposition method using the deposition device.

A magnet assembly according to an embodiment may include a yoke plate disposed on a plane, and a magnetic field generator which is disposed on the yoke plate and includes magnet parts including magnet units, magnetic bodies, and non-magnetic bodies. The magnetic bodies may overlap the magnet parts in a plan view, the non-magnetic bodies may overlap an area between the magnet units in a plan view, the magnet assembly may operate in one of a first mode and a second mode, and the magnetic field generator may generate a magnetic field below the magnetic bodies and the non-magnetic bodies in the first mode and may not substantially generate the magnetic field below the magnetic bodies and the non-magnetic bodies in the second mode.

According to embodiments, the magnetic bodies may include iron (Fe). The non-magnetic bodies may include brass (Cu—Zn).

According to embodiments, the magnet units may include the magnet units spaced apart from each other.

According to embodiments, the magnet units may be arranged in a matrix structure in a first direction and a second direction different from the first direction.

According to embodiments, the magnetic bodies and the non-magnetic bodies may extend in the second direction and may be adjacent to each other in the first direction.

According to embodiments, the first mode, the magnet units may have a same polarity in the second direction, and the magnet units adjacent to each other in the first direction may have different polarities.

According to embodiments, the magnetic field generated in the first mode may have a first magnetic field intensity at a position corresponding to a central area of the magnetic bodies and a second magnetic field intensity at a position corresponding to a central area of the non-magnetic bodies. The first magnetic field intensity may be a highest intensity of the magnetic field. The second magnetic field intensity may be a lowest intensity of the magnetic field.

According to embodiments, the magnetic bodies may include adjacent magnetic bodies, and the adjacent magnetic bodies may be spaced apart from each other by a distance in a range of about 1 mm to about 7 mm.

According to embodiments, in the second mode, the magnet units may alternately form different polarities in the first direction and may alternately form different polarities in the second direction.

According to embodiments, the magnet parts may include the magnet units each having a magnet width. The magnetic bodies may have a first width. The non-magnetic bodies may have a second width. The magnet width may be equal to the first width. The first width may be greater than the second width.

According to embodiments, the magnet parts may include the magnet units each having a magnet width. The magnetic bodies may have a first width. The non-magnetic bodies may have a second width. The magnet width may be greater than the first width. The second width may be greater than the first width.

According to embodiments, the magnet parts may include the magnet units each having a magnet width. The magnetic bodies may have a first width. The non-magnetic bodies may have a second width. The magnet width may be less than the first width. The first width may be greater than the second width.

A deposition device according to an embodiment may include a deposition source which is disposed in a chamber and is supplied with a deposition material, a magnet assembly including a yoke plate disposed on a plane and a magnetic field generator which is disposed on the yoke plate and includes magnet parts including magnet units, magnetic bodies, and non-magnetic bodies, and a cool plate disposed between the magnet assembly and the deposition source, The magnetic bodies may overlap the magnet parts in a plan view, the non-magnetic bodies may overlap an area between the magnet units in a plan view, the magnet assembly may operate in one of a first mode and a second mode, and the magnetic field generator may generate a magnetic field below the magnetic assembly and the cool plate in case that the magnet assembly and the cool plate are adjacent to each other in the first mode and may not substantially generate the magnetic field below the magnetic assembly and the cool plate in case that the magnet assembly and the cool plate are spaced apart from each other in the second mode.

A deposition method according to an embodiment may include adjoining a magnet assembly, which operates in one of a first mode and a second mode, and a substrate, bringing the substrate and a mask assembly into close contact with each other, depositing a deposition material on the substrate using the mask assembly, and separating the magnet assembly and the substrate. The magnet assembly may include a yoke plate disposed on a plane and a magnetic field generator which is disposed on the yoke plate and includes magnet parts including magnet units, magnetic bodies, and non-magnetic bodies, and the magnetic field generator may generate a magnetic field below the magnetic bodies and the non-magnetic bodies in the first mode and may not substantially generate the magnetic field below the magnetic bodies and the non-magnetic bodies in the second mode.

According to embodiments, the adjoining may include operating the magnet assembly in the second mode.

According to embodiments, the bringing may include operating the magnet assembly in the first mode.

According to embodiments, the adjoining may include allowing the substrate and the magnet assembly to be adjacent to each other with a cool plate interposed between the substrate and the magnet assembly. The bringing may include entering the magnet assembly into the first mode in case that the magnet assembly and the cool plate are in contact with each other.

According to embodiments, the separating may include operating the magnet assembly in the second mode.

According to embodiments, in the separating, after the magnet assembly enters the second mode, a contact state between the magnet assembly and the cool plate may be released.

According to embodiments, the mask assembly may include a fine metal mask.

### BRIEF DESCRIPTION OF THE DRAWINGS

FIG. 1 is a schematic cross-sectional view illustrating a deposition device according to an embodiment.

FIG. 2 is a schematic cross-sectional view illustrating a magnet assembly including a magnetic field generator according to an embodiment.

FIG. 3 is a schematic cross-sectional view illustrating a magnet assembly including a magnetic field generator according to an embodiment.

FIG. 4 is a schematic cross-sectional view illustrating a magnet assembly including a magnetic field generator according to an embodiment.

FIG. 5 is a schematic plan view illustrating the magnet assembly including the magnetic field generator according to an embodiment.

FIGS. 6 to 10 are schematic views illustrating operation modes of the magnetic field generator according to an embodiment.

FIG. 11 is a flowchart illustrating a deposition method according to an embodiment.

FIGS. 12 to 14 are schematic cross-sectional views illustrating each process operation of the deposition method according to an embodiment.

### DETAILED DESCRIPTION OF THE EMBODIMENTS

It will be apparent to those skilled in the art that various modifications and variations can be made in the disclosure without departing from the spirit or scope of the disclosure, and specific embodiments are illustrated in the drawings and explained in the detailed description. However, it should be understood that this is not intended to limit the disclosure to a specific disclosed form, and includes all modifications, equivalents, and substitutes included in the technical scope of the disclosure.

Since the disclosure can apply various transformations and have various embodiments, specific embodiments will be illustrated in the drawings and described in detail in the detailed description. However, it should be understood that this is not intended to limit the disclosure to a specific disclosed form, and includes all modifications, equivalents, and substitutes included in the technical scope of the disclosure.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” “has,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a magnet assembly, a deposition device including the magnet assembly, and a deposition method using the deposition device. Hereinafter, the magnet assembly, the deposition device including the magnet assembly, and a deposition method using the deposition device according to embodiments will be described with reference to the accompanying drawings.

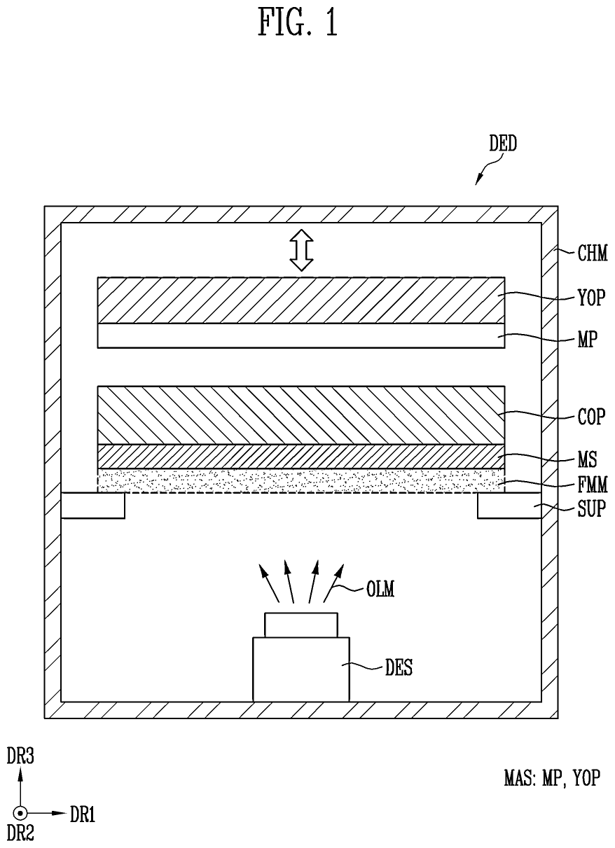

FIG. 1 is a schematic cross-sectional view illustrating a deposition device according to an embodiment.

Referring to FIG. 1, a deposition device DED may include a chamber CHM, a deposition source DES, a support SUP, a mask assembly FMM, a cool plate COP, and a magnet assembly MAS.

The deposition device DED may deposit a deposition material OLM provided from the deposition source DES on a substrate MS.

The deposition material OLM may be formed on the substrate MS in the chamber CHM. The deposition material OLM may include an organic material, but the disclosure is not limited thereto. The deposition material OLM may include a material for forming an emission layer of an organic light-emitting element to be manufactured.

The substrate MS may include a mother substrate. During a deposition process is performed, the substrate MS may be disposed between the cool plate COP and the mask assembly FMM.

The chamber CHM may accommodate the deposition source DES, the support SUP, the mask assembly FMM, the cool plate COP, and the magnet assembly MAS.

The deposition source DES may store the deposition material OLM and may spray the deposition material OLM toward the mask assembly FMM and the substrate MS.

The support SUP may support a lower portion of the mask assembly FMM. The support SUP may provide a base on which the mask assembly FMM may be disposed.

The mask assembly FMM may be disposed to be fixed onto the support SUP. During a deposition process is performed, the mask assembly FMM may be adjacent (for example, directly adjacent) to the substrate MS.

The mask assembly FMM may be disposed between the deposition source DES and the substrate MS so that the deposition material OLM may be patterned on the substrate MS.

According to embodiments, the mask assembly FMM may include a fine metal mask.

The cool plate COP may be disposed between the substrate MS and the magnet assembly MAS. During a deposition process is performed, the cool plate COP may push the substrate MS, thereby bringing the substrate MS and the mask assembly FMM into close contact with each other.

According to embodiments, the cool plate COP may include a non-magnetic material. For example, the cool plate COP may have a structure in which a material (for example, glass) is coated with a non-magnetic material. However, the disclosure is not limited thereto.

The magnet assembly MAS may be disposed above a side of the substrate MS. The magnet assembly MAS may be disposed above a side of the substrate MS with the cool plate COP interposed between the magnet assembly MAS and the substrate MS. During a deposition process is performed, the magnet assembly MAS may be moved adjacent to the cool plate COP. For example, the magnet assembly MAS may be lifted or lowered in a third direction DR3.

The magnet assembly MAS may be a sample holder for fixing the movement of the substrate MS. For example, the magnet assembly MAS may generate a magnetic field, thereby pulling the mask assembly FMM. Accordingly, during a deposition process, a risk of lifting between the mask assembly FMM and the substrate MS may be reduced, and a shadow effect generated during the deposition process may be improved.

The magnet assembly MAS may include a yoke plate YOP and a magnetic field generator MP.

The yoke plate YOP may include a plate that may form a base on which the magnetic field generator MP may be formed. According to embodiments, the yoke plate YOP may include a magnetic material such as stainless steel or the like. However, the disclosure is not limited thereto.

The yoke plate YOP may be disposed on a plane. In the specification, a plane may be defined by a first direction DR1 and a second direction DR2. For example, at least a portion of the plane may extend in the first direction DR1, and at least another portion of the plane may extend in the second direction DR2.

The magnetic field generator MP may be disposed on a surface of the yoke plate YOP (for example, a surface facing the cool plate COP). The magnetic field generator MP may be disposed between the yoke plate YOP and the cool plate COP.

The magnetic field generator MP may generate a magnetic field. In a state in which the magnet assembly MAS is adjacent to the cool plate COP, a magnetic field generated by the magnetic field generator MP may pull the mask assembly FMM, and accordingly, the mask assembly FMM and the substrate MS may be in close contact with each other.

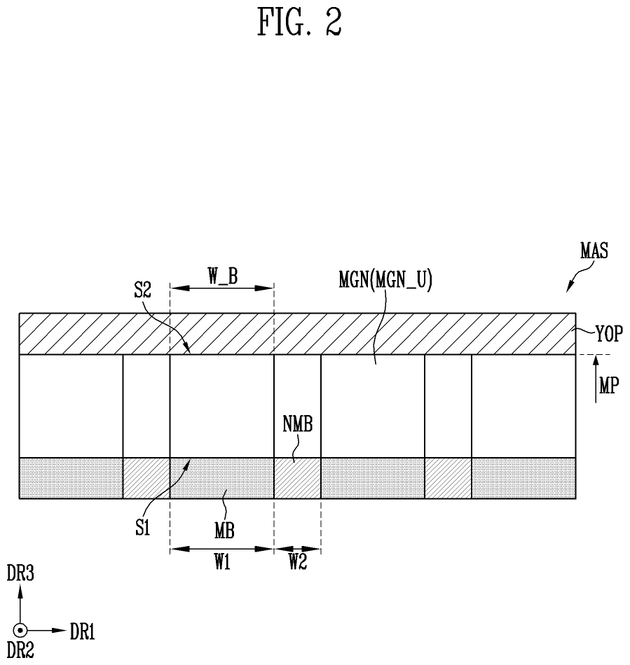

The magnet assembly MAS including the magnetic field generator MP will be described with reference to FIGS. 2 to 10.

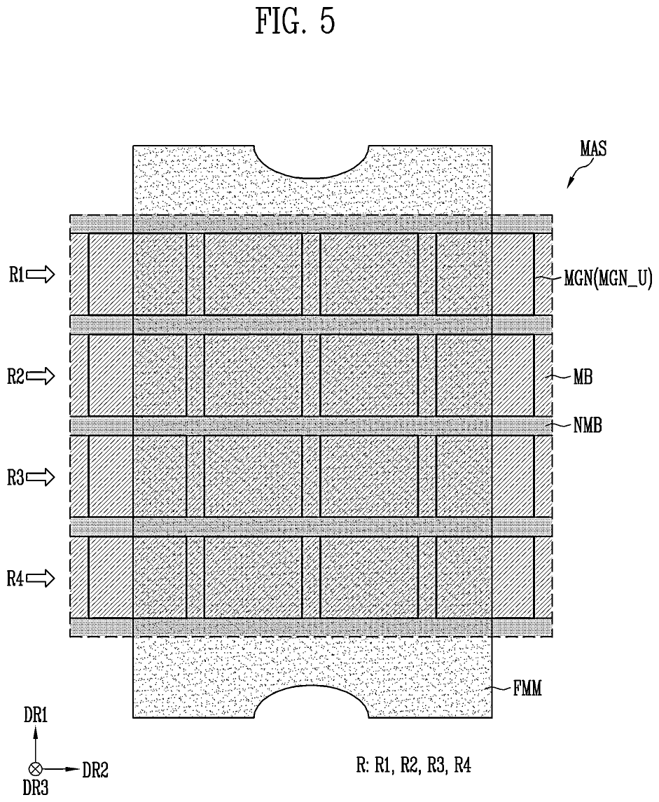

FIGS. 2 to 4 are schematic cross-sectional views illustrating the magnet assembly including the magnetic field generator according to an embodiment. FIG. 5 is a schematic plan view illustrating the magnet assembly including the magnetic field generator according to an embodiment. FIG. 5 is a plan view for describing a positional relationship in a plan view between the mask assembly FMM and the magnet part MGN during a deposition process is performed. For reference, the substrate MS is omitted in FIG. 5 such that an arrangement relationship between components may be more clearly understood.

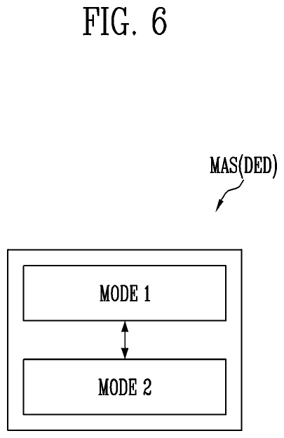

FIGS. 6 to 10 are schematic views illustrating operation modes of the magnetic field generator according to an embodiment. FIG. 6 is a block diagram illustrating the operation modes of the magnetic field generator MP.

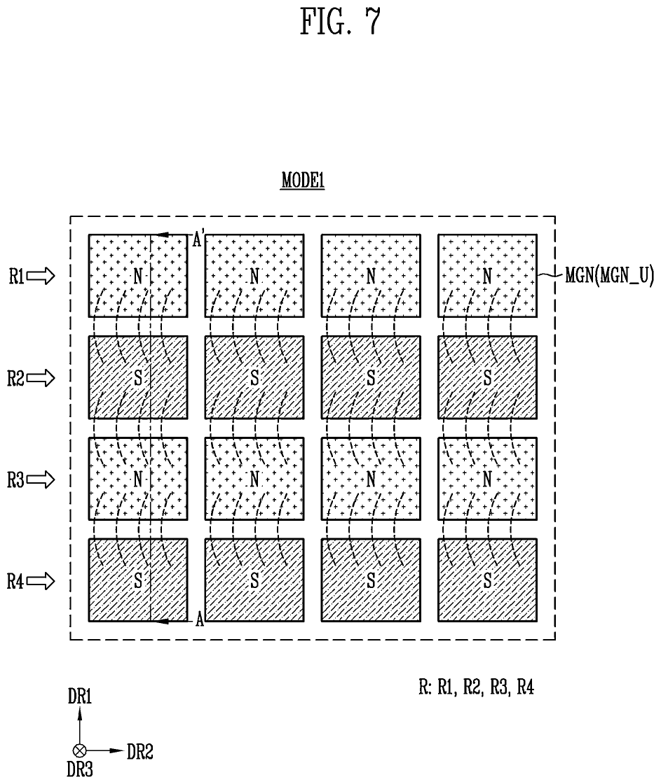

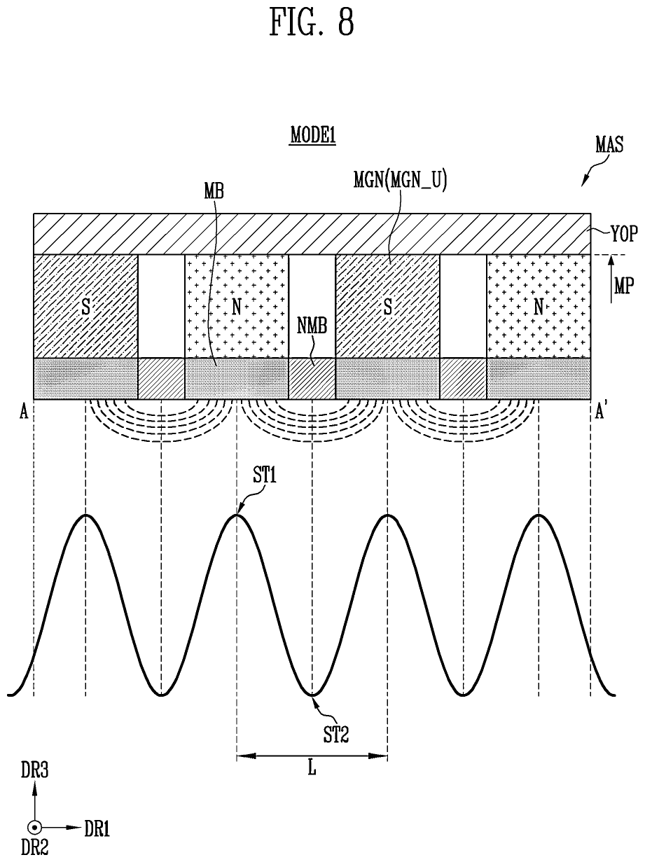

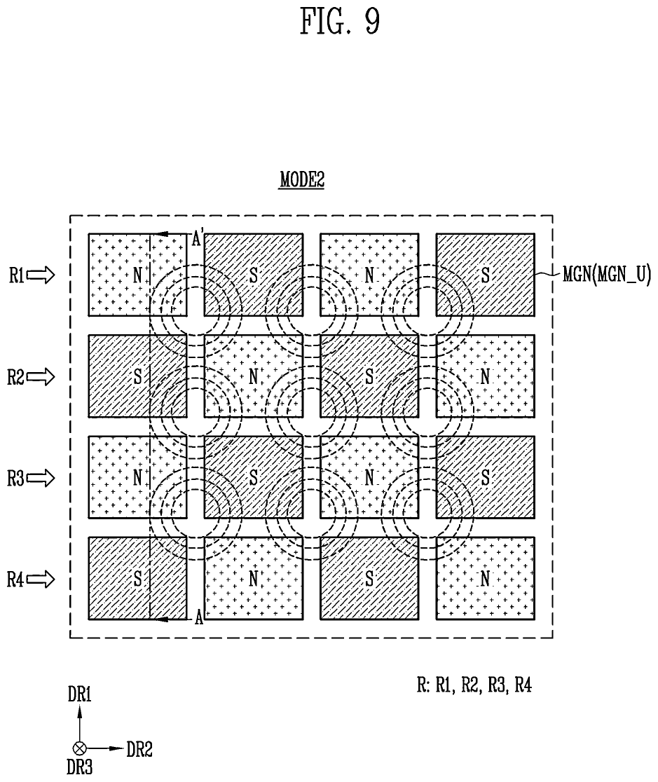

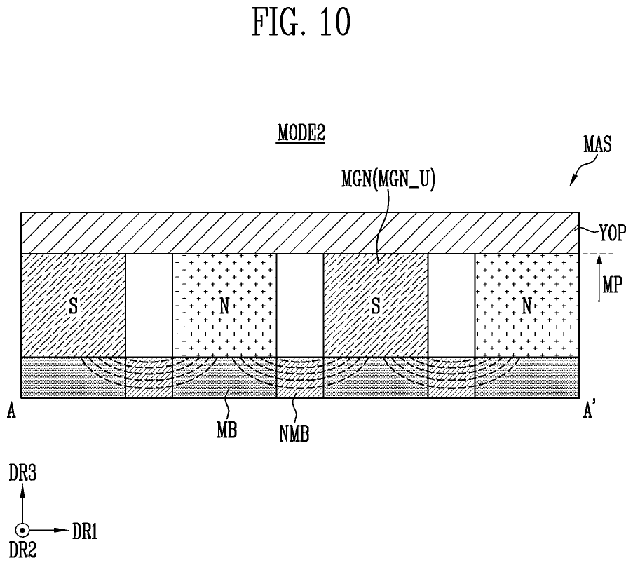

FIGS. 7 and 8 are schematic views illustrating that the magnetic field generator MP operates in a first mode MODEL. FIGS. 9 and 10 are schematic views illustrating that the magnetic field generator MP operates in a second mode MODE2.

FIGS. 7 to 10 illustrate magnetic force lines of a magnetic field, which is generated by the magnetic field generator MP, with dotted lines.

For convenience of description, FIGS. 8 and 10 illustrate the operation modes of the magnetic field generator MP based on a cross-sectional structure of FIG. 2 described above. FIGS. 8 and 10 are schematic cross-sectional views taken along lines A to A′ of FIGS. 7 and 9, respectively.

Referring to FIGS. 2 to 5, the magnetic field generator MP may include magnet parts MGN, magnetic bodies MB, and non-magnetic bodies NMB.

The magnet part MGN may be disposed on a side of the yoke plate YOP. The magnet part MGN may be disposed between the yoke plate YOP and the magnetic body MB. In another embodiment, the magnet part MGN may be disposed between the yoke plate YOP and the non-magnetic body NMB.

The magnet part MGN may have a first surface S1 facing the magnetic body MB or the non-magnetic body NMB and a second surface S2 facing the yoke plate YOP.

According to embodiments, the second surface S2 of the magnet part MGN may be adjacent (for example, directly adjacent) to the yoke plate YOP. According to embodiments, the first surface S1 of the magnet part MGN may be adjacent (for example, directly adjacent) to the magnetic body MB. According to embodiments, the first surface S1 of the magnet part MGN may be adjacent (for example, directly adjacent) to the non-magnetic body NMB.

The magnet part MGN may include a permanent magnet. For example, the magnet part MGN may include a ferromagnetic body including a ferrite-based magnet, a neodymium-based magnet, or a samarium-cobalt-based magnet. However, the disclosure is not limited thereto.

The magnet parts MGN may include magnet units MGN_U spaced apart from each other. For example, the magnet units MGN_U may be spaced apart from each other in the first direction DR1 and may be spaced apart from each other in the second direction DR2. According to embodiments, the magnet units MGN_U may be arranged in a matrix structure in the first direction DR1 and the second direction DR2 different from the first direction DR1. The first direction DR1 may be a row direction, and the second direction DR2 may be a column direction.

For example, the magnet units MGN_U may be sequentially arranged in each of rows R. The rows R may include a first row R1, a second row R2, a third row R3, and a fourth row R4. The magnet units MGN_U may be sequentially arranged in each of the rows.

According to embodiments, the magnetic bodies MB may extend in the second direction DR2. The magnetic bodies MB may be adjacent to each other in the first direction DR1. The non-magnetic bodies NMB may extend in the second direction DR2. Non-magnetic bodies NMB may be adjacent to each other in the first direction DR1.

According to embodiments, the magnetic bodies MB and the non-magnetic bodies NMB may be alternately disposed in the second direction DR2. According to embodiments, the non-magnetic body NMB may be disposed between the magnet units MGN_U in each of adjacent rows R.

According to embodiments, during a deposition process is performed, the mask assembly FMM including a pattern area and a non-pattern area and the magnet assembly MAS may be adjacent to each other (or overlap each other) in a thickness direction.

The pattern area may be a transmissive area of the mask assembly FMM. The non-pattern area may be a non-transmissive area of the mask assembly FMM.

According to embodiments, the position of the non-pattern area may generally correspond to the position of the magnetic body MB and the magnet part MGN. The position of the pattern area may generally correspond to the positions of the non-magnetic body NMB.

According to embodiments, the polarity of each of the magnet units MGN_U may be maintained or changed according to the operation modes of the magnet assembly MAS. Accordingly, in case that the deposition device DED including the magnet assembly MAS according to the embodiment performs a deposition process, a pattern structure formed using the mask assembly FMM may become finer. The details thereof will be described below with reference to FIGS. 6 to 10.

The magnetic body MB may be disposed on the first surface S1 of the magnet part MGN. The magnetic body MB may be adjacent (for example, directly adjacent) to the magnet units MGN_U.

The magnetic body MB may include a material having magnetism. For example, the magnetic body MB may include iron (Fe). However, the disclosure is not limited thereto.

The magnetic body MB may be adjacent to the non-magnetic body NMB in a planar direction. For example, the magnetic body MB and the non-magnetic body NMB may not overlap each other in a plan view.

The non-magnetic body NMB may include a non-magnetic material. The non-magnetic body NMB may have less magnetism than magnetic body MB. For example, the non-magnetic body NMB may include brass (Cu—Zn). However, the disclosure is not limited thereto.

The magnet unit MGN_U may have a magnetic width W_B. The magnetic body MB may have a first width W1. The non-magnetic body NMB may have a second width W2.

According to embodiments, the magnetic width W_B, the first width W1, and the second width W2 may be defined in the planar direction in which the yoke plate YOP is disposed. For example, the magnetic width W_B, the first width W1, and the second width W2 may be defined in the first direction DR1 or the second direction DR2.

According to embodiments (see FIG. 2), the magnetic width W_B may be equal to the first width W1. The magnetic width W_B and the first width W1 may be greater than the second width W2.

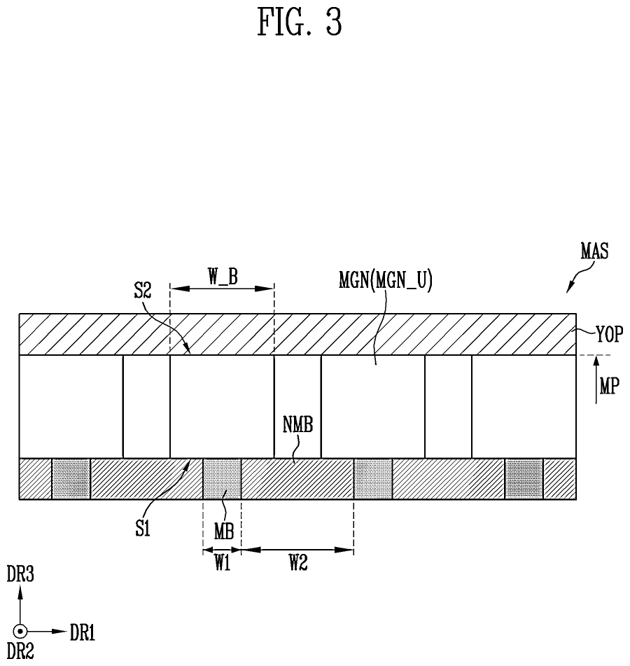

According to embodiments (see FIG. 3), the magnetic width W_B may be greater than the first width W1. The second width W2 may be greater than the first width W1.

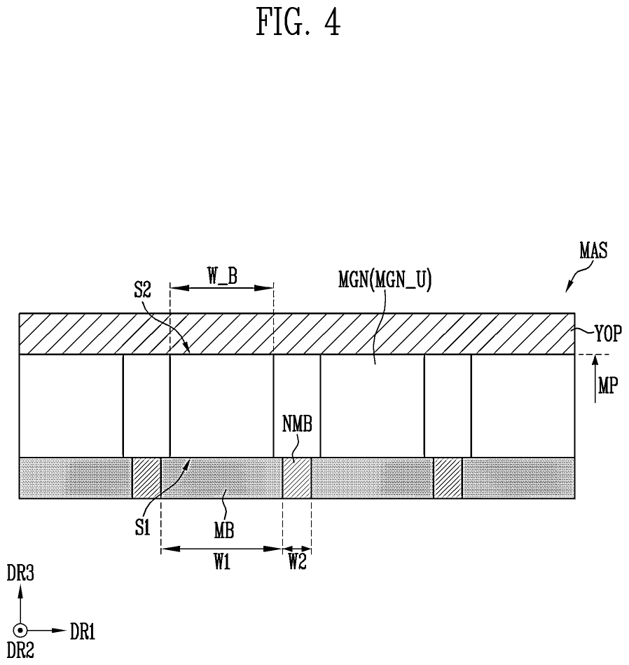

According to embodiments (see FIG. 4), the magnetic width W_B may be less than the first width W1. The first width W1 may be greater than the second width W2.

According to embodiments, multiple magnetic bodies MB and multiple non-magnetic bodies NMB may be provided and may be adjacent to each other in a direction. According to embodiments, the magnetic bodies MB and the non-magnetic bodies NMB may extend in the second direction DR2. The magnetic bodies MB and the non-magnetic bodies NMB may be alternately arranged in the first direction DR1.

According to embodiments, the magnet assembly MAS may include a structure in which the magnetic body MB and the non-magnetic body NMB are disposed adjacent to each other on a plane on the magnet part MGN, and a pattern structure of the mask assembly FMM may become finer, and mechanical noise during a deposition process may be reduced.

With reference to FIGS. 6 to 10, the operation mode of the magnetic field generator MP (or magnet assembly MAS) will be described, and the technical effects implemented by the magnetic field generator (MP (or magnet assembly MAS) according to the embodiment will be described.

Referring to FIGS. 6 to 10, the magnetic field generator MP (or magnet assembly MAS) may be provided to operate in the first mode MODE1 or the second mode MODE2.

According to embodiments, the deposition device DED may include a controller configured to control the overall operation of components included in the deposition device DED.

The controller may change the operation mode of the magnetic field generator MP. The controller may be implemented as a central processing unit (CPU) or a device similar thereto according to hardware, software, or a combination thereof. The controller may be provided in the form of an electronic circuit that processes an electrical signal and performs a control function in terms of hardware. The controller may be provided in the form of a program, an application, or firmware processed by a hardware controller in terms of software.

Referring to FIGS. 6 to 8, the magnetic field generator MP may operate in the first mode MODE1. The magnetic field generator MP may enter the first mode MODE1 from the second mode MOD2.

In the first mode MODE1, the magnetic field generator MP may generate a magnetic field in an area outside the magnetic field generator MP. For example, the first mode MODE1 may be an operation mode performed in case that the magnet assembly MAS including the magnetic field generator MP brings the substrate MS and the mask assembly FMM into close contact with each other.

For example, in the first mode MODE1, the magnetic field generator MP may generate a magnetic field below the magnetic body MB and the non-magnetic body NMB. Accordingly, the magnetic field may be generated below the magnetic field generator MP (for example, below the magnetic body MB and the non-magnetic body NMB).

According to embodiments, in the first mode MODE1, the magnet units MGN_U arranged in the second direction DR2 may have a same polarity. In the first mode MODE1, the magnet units MGN_U adjacent to each other in the first direction DR1 may have different polarities. For example, the magnet units MGN_U disposed in the first row R1 and the third row R3 may have an N pole. The magnet units MGN_U disposed in the second row R2 and the fourth row R4 may have an S pole. Accordingly, the magnet units MGN_U may generate a magnetic field between adjacent rows R. The generated magnetic field may have a relatively high intensity between adjacent rows R and may have a relatively low intensity at positions at which the magnet units MGN_U are disposed arranged in each of the rows R.

According to embodiments, the generated magnetic field may have a first magnetic field intensity ST1 in an area. For example, the first magnetic field intensity ST1 may be the highest magnetic field intensity of the generated magnetic field. A position at which the first magnetic field intensity ST1 is generated may overlap an area in which the magnet part MGN is disposed in a plan view. For example, the position at which the first magnetic field intensity ST1 is generated may correspond to a central area of the magnet part MGN in a plan view. The position at which the first magnetic field intensity ST1 is generated may correspond to the central area of the magnetic body MB in a plan view.

According to embodiments, the generated magnetic field may have a second magnetic field intensity ST2 in another area. For example, the second magnetic field intensity ST2 may be the lowest magnetic field intensity of the generated magnetic field. A position at which the second magnetic field intensity ST2 is generated may overlap an area between the magnet parts MGN. For example, the position at which the second magnetic field intensity ST2 is generated may correspond to a central area between the magnet units MGN_U in a plan view. The position at which the second magnetic field intensity ST2 is generated may correspond to a central area of the non-magnetic body NMB in a plan view.

According to embodiments, a distance L between magnetic field positions at which the first magnetic field intensity ST1 is defined may be less than or equal to about 10 mm. The distance L may be a distance between the central areas of adjacent magnetic bodies MB. According to embodiments, the distance L may be in a range of about 1 mm to about 7 mm. According to embodiments, the distance L may be in a range of about 2 mm to about 6 mm. According to embodiments, the distance L may be about 5 mm. However, the disclosure is not limited thereto.

Referring to FIGS. 6, 9, and 10, the magnetic field generator MP may operate in the second mode MODE2. The magnetic field generator MP may enter the second mode MODE2 from the first mode MODEL.

In the second mode MODE2, the magnetic field generator MP may not generate a magnetic field in an area outside the magnetic field generator MP. For example, the second mode MODE2 may be an operation mode performed in case that the magnet assembly MAS including the magnetic field generator MP does not bring the substrate MS and the mask assembly FMM into close contact with each other.

For example, in the second mode MODE2, a magnetic field generated by the magnetic field generator MP may be generated to have a relatively very weak intensity below the magnetic body MB and the non-magnetic body NMB or may not be substantially generated. The magnetic field generator MP may generate a magnetic field in areas in which the magnetic body MB and the non-magnetic body NMB are disposed. Accordingly, a magnetic field having a relatively very weak intensity may be generated below the magnetic field generator MP (for example, below the magnetic body MB and the non-magnetic body NMB) or may not be substantially generated.

According to embodiments, in the second mode MODE2, the magnet units MGN_U disposed in the first direction DR1 may alternately form different polarities. For example, in the first direction DR1, the magnet units MGN_U forming N poles and the magnet units MGN_U forming S poles may be alternately arranged. According to embodiments, in the second mode MODE2, the magnet units MGN_U arranged in the second direction DR2 may alternately form different polarities. For example, in the second direction DR2, the magnet unit MGN_U forming N poles and the magnet units MGN_U forming S poles may be alternately disposed. For example, the magnet units MGN_U disposed in the first row R1 and the third row R3 may sequentially alternately form N poles and S poles. The magnet units MGN_U disposed in the second row R2 and the fourth row R4 may sequentially alternately form S poles and N poles. Accordingly, the magnetic fields generated by adjacent magnet units MGN_U may cancel each other to have relatively low intensities. As a result, due to the magnetic body MB and the non-magnetic body NMB formed below the magnet part MGN, the magnetic field generated in the second mode MODE2 may not be substantially generated below the magnetic body MB and the non-magnetic body NMB or may be generated to have a very low intensity.

Referring to FIG. 5, in order to implement a fine pattern on a display panel or the like, there may be a need to manufacture a pattern area and a non-pattern area to have a fine width. According to embodiments, during a deposition process is performed, the mask assembly FMM may be disposed on the magnet assembly MA, and the substrate MS may be disposed between the magnet assembly MAS and the mask assembly FMM.

In order to properly couple the mask assembly FMM and the magnet assembly MAS in which the pattern area and the non-pattern area are formed more finely, there is a need for the magnet units MGN_U of the magnet assembly MAS to be spaced a narrower interval apart from each other.

According to embodiments, since the magnetic body MB and the non-magnetic body NMB are disposed below the magnet part MGN, the magnet parts MGN may be disposed more finely, and thus the mask assembly FMM may be provided to implement fine patterns.

For example, a magnetic field generated in case that the magnet assembly MAS operates in the first mode MODE1 may be defined by a structure in which the magnetic body MB and the non-magnetic body NMB are arranged. Thus, the generated magnetic field may be fine.

According to a panel to be manufactured, thicknesses of components disposed below the cool plate COP may be different. For example, in case that a double layer mask is disposed on at least a portion of the substrate MS (for example, the mask assembly FMM includes a double layer mask), or the substrate MS is provided to manufacture a display panel including an under panel camera (UPC) structure, the thickness of the components disposed below the cool plate COP may be different.

Experimentally, in case that a deposition process is performed to arrange the magnet assembly MAS on a surface of the cool plate COP, and the substrate MS having a thickness deviation is disposed on another surface of the cool plate COP, it may be desirable that the entirety of an area causing the thickness deviation is disposed to not overlap the magnet parts MGN in a plan view. For example, in case that a portion of the area causing the thickness deviation overlaps the magnet parts MGN and another portion of the area causing the thickness deviation does not overlap the magnet parts MGN, a portion of a generated magnetic field may generate a repulsive force for the mask assembly FMM, which may cause a risk of the mask assembly FMM lifting from the cool plate COP.

However, according to embodiments, the magnet units MGN may be arranged more finely, thereby reducing a risk of the area of the substrate MS causing the thickness deviation being ununiformly disposed. Accordingly, the risk of the mask assembly FMM lifting from the cool plate COP of may be reduced.

According to embodiments, the magnet assembly MAS may operate in one of the first mode MODE1 and the second mode MODE2 according to a process operation of a deposition process, and thus it is possible to reduce a mechanical risk that may occur during the deposition process. The details thereof will be described below with reference to the drawings.

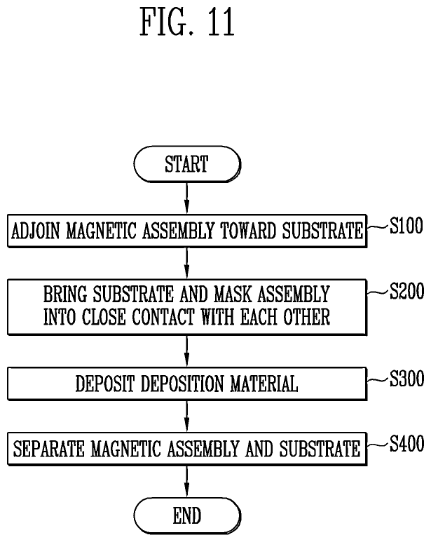

Referring to FIGS. 11 to 14 and the above drawings, a deposition method using a deposition device DED according to an embodiment will be described. For convenience of description, contents that may overlap the above contents will be briefly described or not repeated.

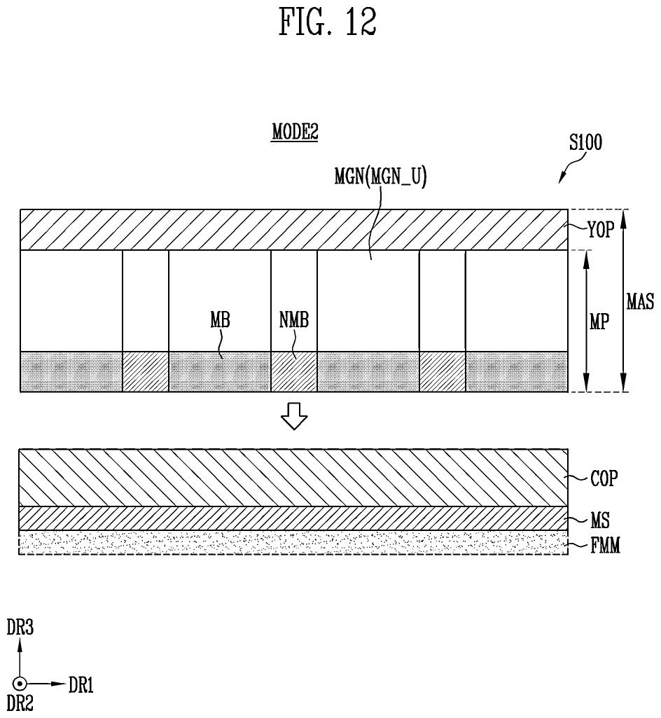

FIG. 11 is a flowchart illustrating a deposition method according to an embodiment. FIGS. 12 to 14 are schematic cross-sectional views illustrating each process operation of the deposition method according to an embodiment.

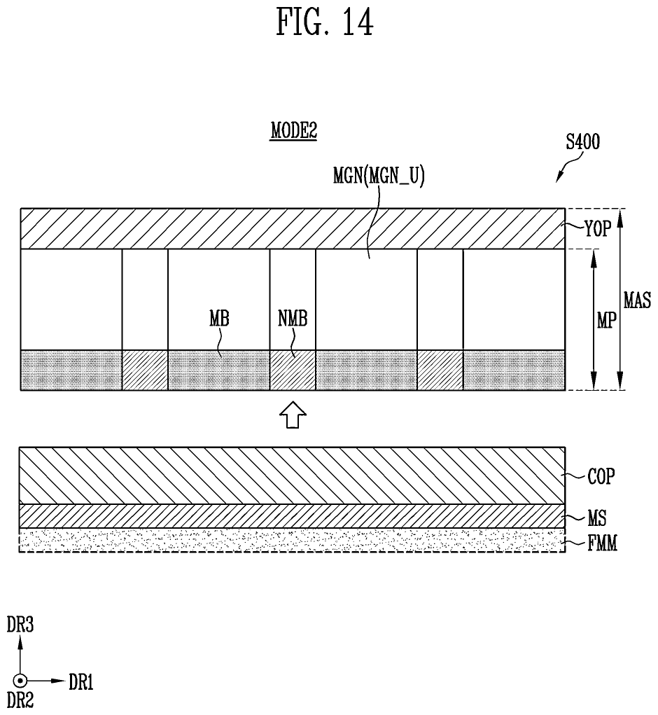

FIGS. 12 and 14 illustrate an embodiment in which a magnet assembly MAS operates in a second mode MODE2, and process operations based on the above-described cross-sectional structure are shown with reference to FIG. 10.

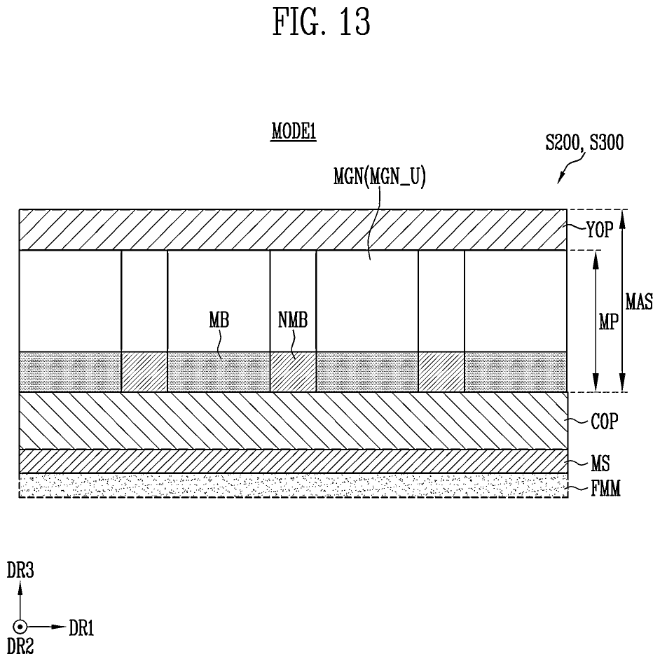

FIG. 13 illustrates an embodiment in which the magnet assembly MAS operates in a first mode MODE1, and process operations based on the above-described cross-sectional structure are shown with reference to FIG. 8.

Referring to FIG. 11, the deposition method using a deposition device DED according to an embodiment may include operation S100 of adjoining a magnet assembly toward a substrate, operation S200 of bringing the substrate and a mask assembly into close contact with each other, operation S300 of depositing a deposition material, and operation S400 of separating the magnet assembly and the substrate.

Referring to FIGS. 11 and 12, in operation S100 of adjoining the magnet assembly toward the substrate, the magnet assembly MAS may be moved adjacent to a substrate MS and a cool plate COP.

In operation S100, the magnet assembly MAS may operate in the second mode MODE2. For example, referring to FIGS. 9 and 10, magnetic fields generated by a magnetic field generator MP may be canceled and generated to be relatively weak below a magnetic body MB and a non-magnetic body NMB or may not be substantially generated.

Experimentally, in case that the magnet assembly MAS is adjacent to the substrate MS and the cool plate COP in a state in which a strong magnetic field is generated below the magnet assembly MAS, in a state in which the magnet assembly MAS is not in close contact with the cool plate COP, mechanical noise (for example, mechanical vibration) may be generated in the substrate MS.

However, according to embodiments, in case that the magnet assembly MAS operates in the second mode MODE2 in which a magnetic field may not generated below the magnet assembly MAS, the magnet assembly MAS may be adjacent to the substrate MS and the cool plate COP so that the above-described risk can be prevented.

Referring FIGS. to 11 and 13, operation S200 of bringing the substrate and the mask assembly into close contact with each other, the magnet assembly MAS may be adjacent (for example, directly adjacent) to the cool plate COP, and accordingly, the substrate MS and the cool plate COP may be in close contact with each other.

In operation S200, the magnet assembly MAS may operate in the first mode MODE1. For example, referring to FIGS. 7 and 8, a magnetic field generated by the magnetic field generator MP may be generated below the magnetic field generator MP.

According to embodiments, in operation S200, the magnet assembly MAS may enter the first mode MODE1 simultaneously in case that the magnet assembly MAS is adjacent (for example, directly adjacent) to the cool plate COP and the substrate MS and the cool plate COP are in close contact with each other.

Accordingly, according to embodiments, an operation of generating a magnetic field below the magnetic field generator MP may be selectively performed at a timing of a process in which the substrate MS and the cool plate COP are brought into close contact with each other.

Referring to FIGS. 11 and 13, in operation S300 of depositing the deposition material, a deposition material OLM may be deposited on the substrate MS.

In operation S300, the magnet assembly MAS may be operated (or maintained) in the first mode MODEL. Accordingly, a magnetic field generated by the magnetic field generator MP may be continuously generated (for example, maintained) below the magnetic field generator MP, and in a state in which the substrate MS is disposed in close contact with the cool plate COP, a deposition process may be performed.

Referring to FIGS. 11 and 14, in operation S400 of separating the magnet assembly and the substrate, the magnet assembly MAS may be physically separated from the cool plate COP, and accordingly, a close contact state between the substrate MS and the cool plate COP may be released.

In operation S400, the magnet assembly MAS may operate in the second mode MODE2. For example, referring to FIGS. 9 and 10, a magnetic field may be generated relatively weak below the magnetic body MB and the non-magnetic body NMB or may not be substantially generated.

According to embodiments, in operation S400, after the magnet assembly MAS enters the second mode MODE2, the magnet assembly MAS may be separated from the cool plate COP. For example, only after the magnet assembly MAS enters the second mode MODE2, the contact state between the magnet assembly MAS and the cool plate COP may be released. Since the magnet assembly MAS may be separated from the cool plate COP after a magnetic field applied to the mask assembly FMM is blocked, according to the movement of the magnet assembly MAS, unnecessary vibration or movement of the substrate MS may be prevented. Accordingly, mechanical noise of the substrate MS may be reduced, and process reliability may be improved.

According to embodiments of the disclosure, there may be provided a magnet assembly in which a deposition process is more finely controlled, thereby manufacturing a high-resolution display device, a deposition device including the magnet assembly, and a deposition method using the deposition device.

One object of the disclosure is to provide a magnet assembly in which a risk of mechanical deformation of a substrate or the like during a deposition process can be reduced, a deposition device including the magnet assembly, and a deposition method using the deposition device.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A magnet assembly comprising:
a yoke plate disposed on a plane; and
a magnetic field generator which is disposed on the yoke plate and includes magnet parts including magnet units, magnetic bodies, and non-magnetic bodies, wherein
the magnetic bodies overlap the magnet parts in a plan view,
the non-magnetic bodies overlap an area between the magnet units in a plan view,
the magnet assembly operates in one of a first mode and a second mode, and
the magnetic field generator generates a magnetic field below the magnetic bodies and the non-magnetic bodies in the first mode and does not substantially generate the magnetic field below the magnetic bodies and the non-magnetic bodies in the second mode.

2. The magnet assembly of claim 1, wherein
the magnetic bodies include iron (Fe), and
the non-magnetic bodies include brass (Cu—Zn).

3. The magnet assembly of claim 1, wherein the magnet parts include the magnet units spaced apart from each other.

4. The magnet assembly of claim 3, wherein the magnet units are arranged in a matrix structure in a first direction and a second direction different from the first direction.

5. The magnet assembly of claim 4, wherein the magnetic bodies and the non-magnetic bodies extend in the second direction and are adjacent to each other in the first direction.

6. The magnet assembly of claim 5, wherein, in the first mode,
the magnet units have a same polarity in the second direction, and
the magnet units adjacent to each other in the first direction have different polarities.

7. The magnet assembly of claim 6, wherein
the magnetic field generated in the first mode has a first magnetic field intensity at a position corresponding to a central area of the magnetic bodies and a second magnetic field intensity at a position corresponding to a central area of the non-magnetic bodies,
the first magnetic field intensity is a highest intensity of the magnetic field, and
the second magnetic field intensity is a lowest intensity of the magnetic field.

8. The magnet assembly of claim 7, wherein
the magnetic bodies include adjacent magnetic bodies, and
the adjacent magnetic bodies are spaced apart from each other by a distance in a range of about 1 mm to about 7 mm.

9. The magnet assembly of claim 5, wherein, in the second mode, the magnet units alternately form different polarities in the first direction and alternately form different polarities in the second direction.

10. The magnet assembly of claim 1, wherein
the magnet part includes the magnet units each having a magnet width,
the magnetic bodies have a first width,
the non-magnetic bodies have a second width,
the magnet width is equal to the first width, and
the first width is greater than the second width.

11. The magnet assembly of claim 1, wherein
the magnet part includes the magnet units each having a magnet width,
the magnetic bodies have a first width,
the non-magnetic bodies have a second width,
the magnet width is greater than the first width, and
the second width is greater than the first width.

12. The magnet assembly of claim 1, wherein
the magnet part includes the magnet units each having a magnet width,
the magnetic bodies have a first width,
the non-magnetic bodies have a second width,
the magnet width is less than the first width, and
the first width is greater than the second width.

13. A deposition device comprising:
a deposition source which is disposed in a chamber and is supplied with a deposition material;
a magnet assembly including a yoke plate disposed on a plane and a magnetic field generator which is disposed on the yoke plate and includes magnet parts including magnet units, magnetic bodies, and non-magnetic bodies; and
a cool plate disposed between the magnet assembly and the deposition source, wherein
the magnetic bodies overlap the magnet parts in a plan view,
the non-magnetic bodies overlap an area between the magnet units in a plan view,
the magnet assembly operates in one of a first mode and a second mode, and
the magnetic field generator generates a magnetic field below the magnetic assembly and the cool plate in case that the magnet assembly and the cool plate are adjacent to each other in the first mode and does not substantially generate the magnetic field below the magnetic assembly and the cool plate in case that the magnet assembly and the cool plate are spaced apart from each other in the second mode.

14. A deposition method comprising:
adjoining a magnet assembly, which operates in one of a first mode and a second mode, and a substrate;
bringing the substrate and a mask assembly into close contact with each other;
depositing a deposition material on the substrate using the mask assembly; and
separating the magnet assembly and the substrate, wherein
the magnet assembly includes a yoke plate disposed on a plane and a magnetic field generator which is disposed on the yoke plate and includes magnet parts including magnet units, magnetic bodies, and non-magnetic bodies, and
the magnetic field generator generates a magnetic field below the magnetic bodies and the non-magnetic bodies in the first mode and does not substantially generate the magnetic field below the magnetic bodies and the non-magnetic bodies in the second mode.

15. The deposition method of claim 14, wherein the adjoining includes operating the magnet assembly in the second mode.

16. The deposition method of claim 14, wherein the bringing includes operating the magnet assembly in the first mode.

17. The deposition method of claim 16, wherein
the adjoining includes allowing the substrate and the magnet assembly to be adjacent to each other with a cool plate interposed between the substrate and the magnet assembly, and
the bringing includes entering the magnet assembly into the first mode in case that the magnet assembly and the cool plate are in contact with each other.

18. The deposition method of claim 17, wherein the separating includes operating the magnet assembly in the second mode.

19. The deposition method of claim 18, wherein, in the separating, after the magnet assembly enters the second mode, a contact state between the magnet assembly and the cool plate is released.

20. The deposition method of claim 14, wherein the mask assembly includes a fine metal mask.
